(19) United States
(12) Patent Application Publication
(10) Pub. No.: US 2014/0022750 A1
(43) Pub. Date: Jan. 23, 2014

(54) CIRCUIT BOARD AND METHOD OF MANUFACTURING THE SAME

(71) Applicant: Murata Manufacturing Co., Ltd., Nagaokakyo-shi (JP)

(72) Inventors: Yoichi MORIYA, Nagaokakyo-shi (JP); Satoshi ITO, Nagaokakyo-shi (JP); Tetsuo KANAMORI, Nagaokakyo-shi (JP); Yukihiro YAGI, Nagaokakyo-shi (JP); Yuki YAMAMOTO, Nagaokakyo-shi (JP)

(73) Assignee: Murata Manufacturing Co., Ltd., Nagaokakyo-shi (JP)

(21) Appl. No.: 14/037,818

(22) Filed: Sep. 26, 2013

Related U.S. Application Data
(63) Continuation of application No. PCT/JP2012/057883, filed on Mar. 27, 2012.

(30) Foreign Application Priority Data
Mar. 28, 2011 (JP) 2011-069094

(51) Int. Cl. H05K 1/02; H05K 3/06

(52) U.S. Cl. CPC H05K 1/0265; H05K 3/06
USPC 361/760; 174/250; 174/251; 174/257; 216/19

(57) ABSTRACT

A circuit board includes an insulating layer with a surface on which a semiconductor element is to be mounted and wiring portions that are located on the insulating layer. The wiring portions includes upper wiring portions, lower wiring portions, and interlayer wiring portions. The upper wiring portions, the lower wiring portions, and the interlayer wiring portions are integrally defined by a single copper sheet. With this configuration, a circuit board capable of withstanding a large current and a method of manufacturing the circuit board are provided.

### BACKGROUND OF THE INVENTION

1. Field of the Invention

The present invention relates to a circuit board capable of withstanding a large current and a method of manufacturing the circuit board.

2. Description of the Related Art

A common circuit board has a configuration in which an electrically conductive wiring pattern is formed on a substrate made of an insulating resin or the like. Since a large current may sometimes be needed depending on a device on which such a circuit board is to be mounted or the like, a circuit board that can withstand a large current by, for example, increasing the thickness of a wiring pattern has been proposed (see, for example, Japanese Unexamined Patent Application Publication No. 2002-76571). FIG. 1 is a diagram schematically illustrating a circuit board that is described in Japanese Unexamined Patent Application Publication No. 2002-76571.

In the circuit board described in Japanese Unexamined Patent Application Publication No. 2002-76571, conductor patterns 102 and 103 that are formed by etching a copper sheet are formed on the top and bottom surfaces of a substrate 101 made of a prepreg. In order to electrically connect the conductor patterns 102 and 103 to each other, through holes 105 extending through the top and bottom surfaces of the substrate 101 are formed, and the top and bottom surfaces of the substrate 101 including the conductor patterns 102 and 103 and the inner surfaces of the through holes 105 are coated with a copper coating 104.

Each of the through holes 105 that are coated with the copper coating 104 functions as a via hole conductor that electrically connects the conductor patterns 102 and 103, which are formed on the top and bottom surfaces of the substrate 101, to each other. In a circuit board having such a configuration, the thickness of each of the conductor patterns 102 and 103 is large, and this enables the circuit board to withstand a large current.

However, in the case of Japanese Unexamined Patent Application Publication No. 2002-76571, since the conductor patterns 102 and 103 are electrically connected to each other by the copper coating 105, even if a large current can flow in the conductor patterns 102 and 103, the thickness of the copper coating 105 also needs to be increased. Therefore, a problem occurs in that the manufacturing time and costs must increase in order to make the copper coating 105 capable of withstanding a large current.

Since the copper film out of which the copper coating 105 is made includes impurities, the resistance of the copper film is larger than that of pure copper, and thus, there has been another problem in that the copper coating 105 that functions as a via hole conductor disrupts the flow of a large current.

### SUMMARY OF THE INVENTION

Accordingly, preferred embodiments of the present invention provide a circuit board capable of withstanding a large current and a method of manufacturing the circuit board.

A circuit board according to a preferred embodiment of the present invention includes an insulating layer and a wiring portion integrally defined by a single electrically conductive metal member, the wiring portion being arranged on the insulating layer such that a portion of the wiring portion is exposed at each of top and bottom surfaces of the insulating layer.

In this configuration, the portion of the wiring portion that is integrally defined by the single electrically conductive metal member is exposed at each of the top and bottom surfaces of the insulating layer. In other words, an electrically conductive wiring pattern that is provided on each of the top and bottom surfaces of an insulating layer and a via hole conductor that electrically connects the wiring patterns to each other are integrally defined by a single electrically conductive metal member.

In the case where the wiring patterns and the via hole conductor are separately provided, the wiring patterns and the via hole conductor are made of different materials and joined with each other, and thus, the resistance of the joint portion becomes large. Therefore, by integrally forming the wiring patterns and the via hole conductor out of a single electrically conductive metal member, a joint interface will not be present between the wiring pattern and the via hole conductor, and the resistance of the wiring portion is significantly reduced. As a result, the circuit board can withstand a large current.

In addition, since the wiring patterns and the via hole conductor are integrally defined by a single unitary member, separation does not occur in the joint portion of the wiring patterns and the via hole conductor, and thus, the joint reliability is improved.

In the circuit board according to a preferred embodiment of the present invention, positions on the top and bottom surfaces of the insulating layer where the portions of the wiring portion are exposed may be not superposed with each other in a top-bottom direction of the insulating layer.

In this configuration, the wiring portion does not have a linear shape along the top-bottom direction of the insulating layer, and thus, a possibility that the wiring portion comes off from the insulating layer is significantly reduced or prevented.

In the circuit board according to a preferred embodiment of the present invention, the wiring portion may include a column along the top-bottom direction of the insulating layer and the column expands gradually from the top and bottom surfaces of the insulating layer to a center portion of the wiring portion in the top-bottom direction.

In this configuration, the wiring portion includes the column having a center portion that expands, and thus, the possibility that the wiring portion comes off from the insulating layer is significantly reduced or prevented.

In the circuit board according to a preferred embodiment of the present invention, a nickel plating film may be provided on the portions of the wiring portion exposed at the top and bottom surfaces of the insulating layer.

In this configuration, the strength of the exposed portion is secured by forming the nickel plating film, for example.

In the circuit board according to a preferred embodiment of the present invention, an electronic component may be directly mounted on the portion of the wiring portion exposed at the top surface of the insulating layer.

In this configuration, a recess is not likely to be generated in the exposed portion, and the degree of flatness of the exposed portion is high compared with the case where a through hole is filled with a plating, and thus, an electronic component can be directly mounted, and it is not necessary to provide a land.

In the circuit board according to a preferred embodiment of the present invention, the electronic component may be a power semiconductor element. Here, a power semiconductor element is a semiconductor element for power conversion or a semiconductor element for power control and also referred to as a semiconductor element for power.

In this configuration, a circuit board capable of withstanding a power semiconductor element that operates with a large current at a high voltage is realized.

In the circuit board according to a preferred embodiment of the present invention, the electronic component may be sealed with a resin.

In this configuration, the electronic component can be protected by sealing the electronic component with a resin.

A method of manufacturing a circuit board according to a preferred embodiment of the present invention includes forming a wiring pattern by etching a first surface of a single electrically conductive metal member, filling a portion in the first surface from which the metal member has been removed by etching with a dielectric material, forming a wiring pattern by etching a second surface of the metal member, and filling a portion in the second surface from which the metal member has been removed by etching with a dielectric material.

In this configuration, a circuit board in which wiring patterns formed on the first and the second surfaces of a dielectric material and a via hole conductor that electrically connects the wiring patterns are integrally formed of a single metal member is manufactured. In the case of a circuit board in which wiring patterns and a via hole conductor are separately formed, the wiring patterns and the via hole conductor are formed of different materials and joined with each other, and thus, the resistance of the joint portion becomes large. Therefore, by integrally forming the wiring patterns and the via hole conductor out of a single electrically conductive metal member, a joint interface will not be present between the wiring patterns and the via hole conductor, and the resistance of a wiring portion can be reduced. As a result, a circuit board can withstand a large current. After the wiring pattern is formed on the first surface by etching, the portion in the first surface from which the metal member has been removed is filled with a dielectric material, and thus, after the wiring pattern is formed on the second surface, the wiring patterns will not be separated from each other, and a circuit board in which an insulating layer and a wiring portion are integrated with each other can be manufactured.

According to various preferred embodiments of the present invention, it is possible to make a circuit board capable of withstanding a large current by preventing the resistance of a wiring portion in an insulating layer from becoming large.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a diagram schematically illustrating a circuit board that is described in Japanese Unexamined Patent Application Publication No. 2002-76571.

FIGS. 2A and 2B are schematic diagrams of a circuit board according to a first preferred embodiment of the present invention.

FIGS. 3A-3E are schematic diagrams sequentially illustrating an example of a process of manufacturing the circuit board according to the first preferred embodiment of the present invention.

FIG. 4 is a diagram illustrating another example of the circuit board according to the first preferred embodiment of the present invention.

FIGS. 5A and 5B are schematic diagrams of a circuit board according to a second preferred embodiment of the present invention.

FIGS. 6A-6D are schematic diagrams sequentially illustrating an example of a process of manufacturing the circuit board according to the second preferred embodiment of the present invention.

FIGS. 7A and 7B are diagrams illustrating another example of the circuit board according to the second preferred embodiment of the present invention.

FIGS. 8A and 8B are schematic diagrams of a circuit board according to a third preferred embodiment of the present invention.

FIGS. 9A-9D are schematic diagrams sequentially illustrating an example of a process of manufacturing the circuit board according to the third preferred embodiment of the present invention.

FIGS. 10A-10C are diagrams illustrating another example of the circuit board according to the third preferred embodiment of the present invention.

FIG. 11 is a schematic diagram illustrating a cross-sectional view of a circuit board in which a semiconductor element is sealed with a resin.

### DETAILED DESCRIPTION OF THE PREFERRED EMBODIMENTS

### First Preferred Embodiment

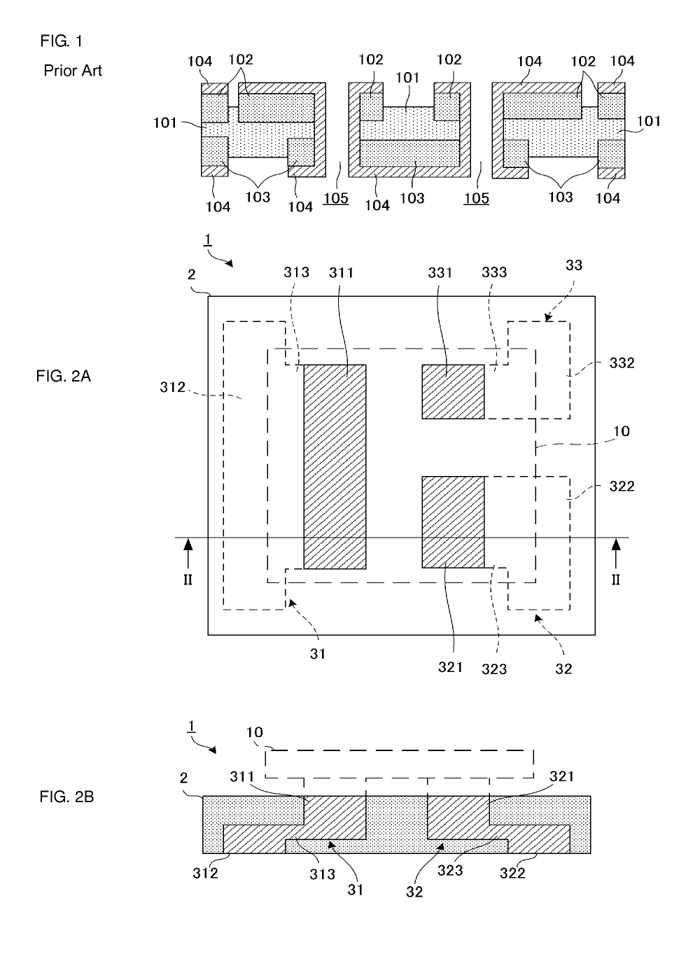

FIGS. 2A and 2B are schematic diagrams of a circuit board according to a first preferred embodiment of the present invention. FIG. 2A is a top view of the circuit board. FIG. 2B is a cross-sectional view taken along line II-II of FIG. 2A. In a circuit board 1 according to the first preferred embodiment, a semiconductor element 10 is mounted on a major surface (the top surface), and the semiconductor element 10 and an electrode of a substrate, an element, a ground, or the like that is connected to a side of the bottom surface are electrically connected to each other.

In the present preferred embodiment, an electronic component that is mounted on the circuit board 1 preferably is the semiconductor element 10. However, the semiconductor element 10 may be suitably changed to, for example, an active element such as a silicon semiconductor element, a gallium arsenide semiconductor element, or the like or a passive element such as a capacitor, an inductor, or the like, for example. In the present preferred embodiment, the semiconductor element 10 preferably is a power semiconductor element that is, for example, a power metal-oxide-semiconductor field-effect transistor (MOSFET), for example.

The circuit board 1 includes an insulating layer 2 and wiring portions 31, 32, and 33. The insulating layer 2 preferably is a sheet-shaped insulating resin and has a rectangular or substantially rectangular parallelepiped shape in which each of the top and bottom surfaces is square-shaped or substantially square-shaped. The semiconductor element 10 is to be mounted on the top surface of the insulating layer 2. An example of the insulating resin is an epoxy resin, a polyimide resin, or the like. The insulating layer 2 may include a single layer or may be multilayered. Four surfaces of the insulating layer 2 located between the top and bottom surfaces of the insulating layer 2 will be hereinafter referred to as side surfaces.

The wiring portions 31, 32, and 33 electrically connect the semiconductor element 10 that is to be mounted on the top surface of the insulating layer 2 and an electrode that is to be connected to the bottom surface of the insulating layer 2. More specifically, the wiring portion 31 is a wiring for a gate terminal of the semiconductor element 10, the wiring portion 32 is a wiring for a source terminal, and the wiring portion 33 is a wiring for a drain terminal.

Each of the wiring portions 31, 32, and 33 preferably includes a single copper sheet. In other words, whereas, in the related art, electrically conductive wiring patterns formed on the top and bottom surfaces of the insulating layer 2 are electrically connected to each other by via hole conductors formed by filling through holes formed in the insulating layer 2 with a resin composition in which metal powder is dispersed, such wiring patterns and such via hole conductors are preferably defined by a single copper sheet as the wiring portions 31, 32, and 33 in the present preferred embodiment.

Therefore, in the related art, the resistance of a wiring path becomes large by joining the wiring patterns and the via hole conductor that are made of different materials together. However, since a joint portion is not present, the resistance of each of the wiring portions 31, 32, and 33 does not become large.

In addition, since the wiring portions 31, 32, and 33 are defined by a single copper sheet, metal component proportion is large, and the resistance of each of the wiring portions 31, 32, and 33 is small compared with the case where a resin composition in which metal powder is dispersed is used.

Therefore, even if the semiconductor element 10 needs a large current, the wiring portions 31, 32, and 33 will not block the flow of a large current.

The wiring portion 31 includes an upper wiring portion 311, a lower wiring portion 312, and an interlayer wiring portion 313.

The upper wiring portion 311 preferably has a rectangular or substantially rectangular parallelepiped shape, each surface of which is rectangular or substantially rectangular. Two of the surfaces of the rectangular or substantially rectangular parallelepiped shape that have the maximum area and that are facing each other are the top and bottom surfaces. The upper wiring portion 311 is arranged such that the longitudinal direction of the rectangular or substantially rectangular parallelepiped is parallel or substantially parallel to one of the side surfaces of the insulating layer 2, and that the top surface of the upper wiring portion 311 is exposed at the top surface of the insulating layer 2. A nickel plating film is provided on the top surface of the upper wiring portion 311, which is exposed at the top surface of the insulating layer 2, and the gate terminal of the semiconductor element 10 is directly connected to the top surface of the upper wiring portion 311. The strength of a portion of the upper wiring portion 311 that is exposed is secured by providing the nickel plating film.

The lower wiring portion 312 has a shape that preferably is substantially the same as that of the upper wiring portion 311, and the length of the lower wiring portion 312 is larger than that of the upper wiring portion 311 in a longitudinal direction. The lower wiring portion 312 is located at a position where the lower wiring portion 312 is not superposed with the upper wiring portion 311 in a top-bottom direction of the insulating layer 2 (a thickness direction) in such a manner that the bottom surface of the lower wiring portion 312 is exposed at the bottom surface of the insulating layer 2. The bottom surface of the lower wiring portion 312, which is exposed at the bottom surface of the insulating layer 2, is to be connected to an electrode of a substrate or the like.

The interlayer wiring portion 313 is a flat plate having a rectangular or substantially rectangular parallelepiped shape that is parallel or substantially parallel to a planar direction (a direction perpendicular or substantially perpendicular to the thickness direction) of the insulating layer 2. A longitudinal direction of the interlayer wiring portion 313 is the same as those of the upper wiring portion 311 and the lower wiring portion 312, and one of two side surfaces of the interlayer wiring portion 313 that are parallel or substantially parallel to each other is connected to a lower portion of the upper wiring portion 311, and the other one of the two side surfaces is connected to an upper portion of the lower wiring portion 312.

As described above, in the wiring portion 31, the upper wiring portion 311, the lower wiring portion 312, and the interlayer wiring portion 313 are integrally defined by a single copper sheet, and thus, there is no joint portion of different materials in the wiring portion 31, and the resistance is prevented from becoming large. In addition, the upper wiring portion 311 and the lower wiring portion 312 are arranged so as not to be superposed with each other in the top-bottom direction, and the upper wiring portion 311 and the lower wiring portion 312 are not linearly arranged in the top-bottom direction of the insulating layer 2, and thus, the wiring portion 31 is prevented from easily coming off from the insulating layer 2.

Each of the upper wiring portion 311, the lower wiring portion 312, and the interlayer wiring portion 313, which are included in the wiring portion 31, preferably has a rectangular or substantially rectangular column shape (a rectangular or substantially rectangular parallelepiped shape), so that the entire volumes of the upper wiring portion 311, the lower wiring portion 312, and the interlayer wiring portion 313 can be large compared with the case where each of the upper wiring portion 311, the lower wiring portion 312, and the interlayer wiring portion 313 have a circular column shape. Thus, the resistance of the wiring portion 31 is significantly reduced. Since the wiring portion 31 is preferably formed by etching a copper sheet (described later), for example, the size or the like of the wiring portion 31 can be easily adjusted when the wiring portion 31 is manufactured compared with the case where each of the upper wiring portion 311, the lower wiring portion 312, and the interlayer wiring portion 313 is formed in a circular column shape.

The wiring portion 32 includes an upper wiring portion 321, a lower wiring portion 322, and an interlayer wiring portion 323. The source terminal of the semiconductor element 10 is connected to the upper wiring portion 321, and the lower wiring portion 322 is electrically connected to an electrode of a substrate or the like.

The wiring portion 33 includes an upper wiring portion 331, a lower wiring portion 332, and an interlayer wiring portion 333. The drain terminal of the semiconductor element 10 is connected to the upper wiring portion 331, and the lower wiring portion 332 is electrically connected to an electrode of a substrate or the like.

Since these wiring portions 32 and 33 have a configuration similar to that of the wiring portion 31 except with respect to the sizes thereof, the descriptions of the wiring portions 32 and 33 will be omitted.

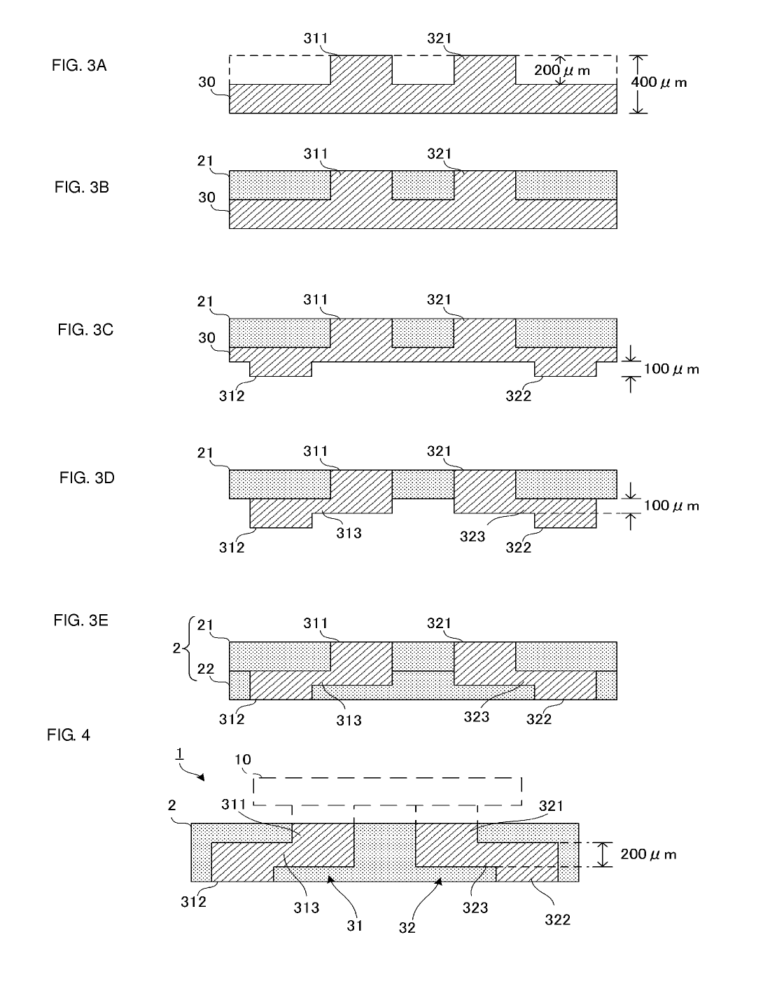

A method of manufacturing the circuit board 1 according to the first preferred embodiment will now be described. FIGS. 3A-3E are schematic diagrams sequentially illustrating an example of a process of manufacturing the circuit board 1 according to the first preferred embodiment. FIGS. 3A-3E are cross-sectional views taken along line II-II of FIG. 2A in the manufacturing process.

In a first step (FIG. 3A), a photosensitive resist film is deposited on the top and bottom surfaces of a copper sheet 30 (a metal member) having a thickness of 400 μm, and exposure, development, and etching are performed by a subtractive method (a method of removing an unnecessary portion and leaving a circuit) in such a manner that a rectangular or substantially rectangular pattern having a thickness of 200 μm is left behind. The pattern that is left behind by etching is the upper wiring portions 311, 321, and 331.

In a second step (FIG. 3B), a portion in the top surface of the copper sheet 30 formed by removing the copper sheet 30 by etching is filled with an insulating resin 21. In this case, the portion is filled with the insulating resin 21 in such a manner that at least the top surface of the pattern that is left behind by etching (the upper wiring portion 311 and the like) is exposed. The insulating resin 21 is, for example, a polyimide resin, and after the portion is filled with the insulating resin 21, the insulating resin 21 is pressed and cured.

In a third step (FIG. 3C), exposure, development, and etching are performed in such a manner that a rectangular or substantially rectangular pattern having a thickness of 100 μm is left behind on the bottom surface of the copper sheet 30. The pattern that is left behind by etching is the lower wiring portions 312, 322, and 332.

In a fourth step (FIG. 3D), a photosensitive resist film is deposited on a portion of the copper sheet 30 that has been exposed in the third step, and exposure, development, and etching are performed in such a manner that a pattern having a thickness of 100 μm that connects the patterns formed in the first and third steps (the upper wiring portion 311, the lower wiring portion 312, and the like) to each other is left behind. The pattern that is formed as a result of this is the interlayer wiring portions 313, 323, and 333.

In a fifth step (FIG. 3E), a portion in the bottom surface of the copper sheet 30 formed by removing the copper sheet 30 by etching is filled with an insulating resin 22. In this case, the portion is filled with the insulating resin 22 in such a manner that at least the bottom surface of the pattern that is left behind by etching (the lower wiring portion 312 and the like) is exposed. The insulating resin 22 is, for example, a polyimide resin, and after the portion is filled with the insulating resin 22, the insulating resin 22 is pressed and cured. The insulating resins 21 and 22 are the insulating layer 2 illustrated in FIG. 2.

Through the first to fifth steps, the circuit board 1 that includes the wiring portions 31, 32, and 33, which are integrally formed of a single copper sheet and each of which includes the upper wiring portion, the lower wiring portion, and the interlayer wiring portion that are not separated from one another, can be manufactured. In addition, as described in the description of the second step illustrated in FIG. 3B, after the upper wiring portions 311, 321, and 331 are formed by etching, the portion in the top surface of the copper sheet 30 formed by removing the copper sheet 30 by etching is filled with the insulating resin 21, and the insulating resin 21 is cured, so that the upper wiring portions 311, 321, and 331 are prevented from being separated from one another in the manufacturing process.

Note that, although the thicknesses of the upper wiring portion 311, the lower wiring portion 312, the interlayer wiring portion 313, and the like have been described using specific values in the present preferred embodiment, the sizes or the like of the upper wiring portion 311, the lower wiring portion 312, the interlayer wiring portion 313, and the like may be suitably changed. FIG. 4 is a diagram illustrating another example of the circuit board 1 according to the first preferred embodiment. Although the thickness of each of the interlayer wiring portions 313, 323, 333 preferably is 100 μm in FIGS. 2A and 2B, the thickness may be, for example, 200 μm in order to further withstand a large current.

In the present preferred embodiment, it is easy to make the top and bottom surfaces of the insulating layer 2 and the surfaces of the wiring portions 31, 32, and 33 that are exposed be in the same plane, and the flatness of the circuit board 1 can be improved. In addition, after the portion formed by removing the copper sheet 30 by etching is filled with the insulating resin (21, 22) several times from the top surface and the bottom surface of the copper sheet 30, the insulating resin (21, 22) is pressed, and thus, a void is not generated between the insulating layer 2 and the wiring portions 31, 32, and 33, so that the circuit board 1 having high adhesion can be obtained.

### Second Preferred Embodiment

In a circuit board according to a second preferred embodiment, wiring portions are different from the wiring portions 31, 32, and 33 of the circuit board 1 according to the first preferred embodiment. More specifically, in the first preferred embodiment, each of the upper wiring portion 311 and the lower wiring portion 312, the upper wiring portion 321 and the lower wiring portion 322, and the upper wiring portion 331 and the lower wiring portion 332 are preferably arranged so as not to be superposed with each other in the top-bottom direction of the insulating layer 2. In contrast, in the second preferred embodiment, each of the upper wiring portion 311 and the lower wiring portion 312, the upper wiring portion 321 and the lower wiring portion 322, and the upper wiring portion 331 and the lower wiring portion 332 are preferably arranged so as to be partially superposed with each other in the top-bottom direction of the insulating layer 2. The difference will be described below.

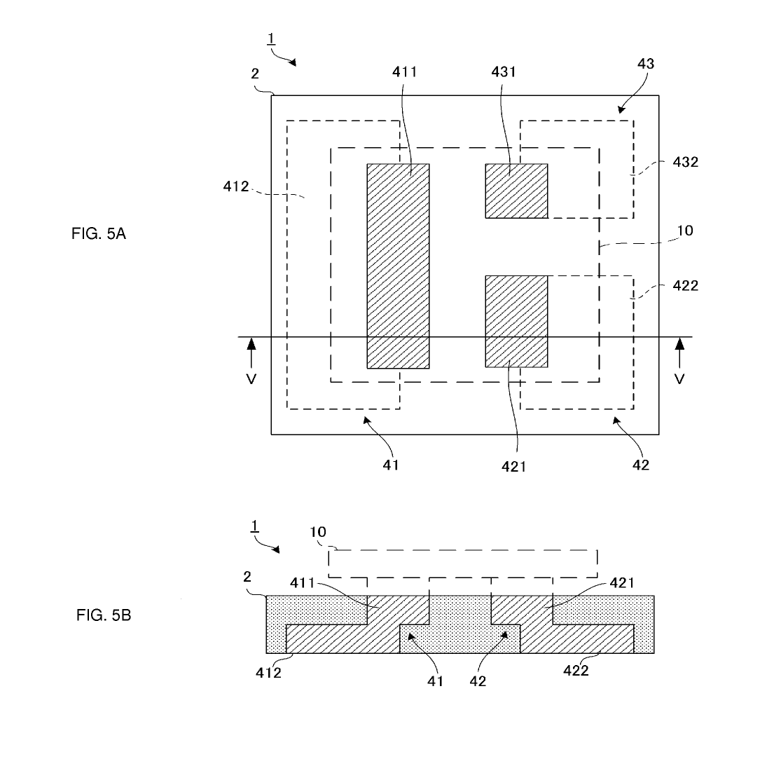

FIGS. 5A and 5B are schematic diagrams of the circuit board according to the second preferred embodiment. FIG. 5A is a top view of the circuit board. FIG. 5B is a cross-sectional view taken along line V-V of FIG. 5A.

A circuit board 1 according to the second preferred embodiment includes an insulating layer 2 and wiring portions 41, 42, and 43. The insulating layer 2 is the same as that of the first preferred embodiment. In a manner similar to the first preferred embodiment, each of the wiring portions 41, 42, and 43 is preferably defined by a single copper sheet.

The wiring portion 41 includes an upper wiring portion 411 and a lower wiring portion 412. In the similar manner to the upper wiring portion 311 of the first preferred embodiment, the upper wiring portion 411 is located on the insulating layer 2.

The lower wiring portion 412 preferably has a shape that is the same or substantially the same as that of the upper wiring portion 411, and the length of the lower wiring portion 412 is larger than that of the upper wiring portion 411 in a longitudinal direction. A portion of the top surface of the lower wiring portion 412 is connected to a portion of the bottom surface of the upper wiring portion 411, and the lower wiring portion 412 is arranged such that the bottom surface thereof is exposed at the bottom surface of the insulating layer 2. In other words, as illustrated in FIG. 5A, the lower wiring portion 412 is partially superposed with the upper wiring portion 411 when viewed from the top surface.

As described above, in the wiring portion 41, the upper wiring portion 411 and the lower wiring portion 412 are integrally defined by a single copper sheet, and thus, there is no joint portion of different materials in the wiring portion 41, and the resistance is prevented from becoming large. In addition, since the upper wiring portion 411 and the lower wiring portion 412 are partially superposed with each other in the top-bottom direction, the interlayer wiring portion 313 according to the first preferred embodiment is not necessary, and thus, the circuit board 1 can further withstand a large current. Since the upper wiring portion 411 and the lower wiring portion 412 are not completely superposed with each other in the top-bottom direction, the wiring portion 41 will not easily come off from the insulating layer 2.

The wiring portion 42 includes an upper wiring portion 421 and a lower wiring portion 422. A source terminal of a semiconductor element 10 is connected to the upper wiring portion 421, and the lower wiring portion 422 is electrically connected to an electrode of a substrate or the like. The wiring portion includes an upper wiring portion 431 and a lower wiring portion 432. A drain terminal of the semiconductor element 10 is connected to the upper wiring portion 431, and the lower wiring portion 432 is electrically connected to an electrode of a substrate or the like.

Since these wiring portions 42 and 43 have a configuration similar to that of the wiring portion 41 except with respect to the sizes thereof, the descriptions of the wiring portions 42 and 43 will be omitted.

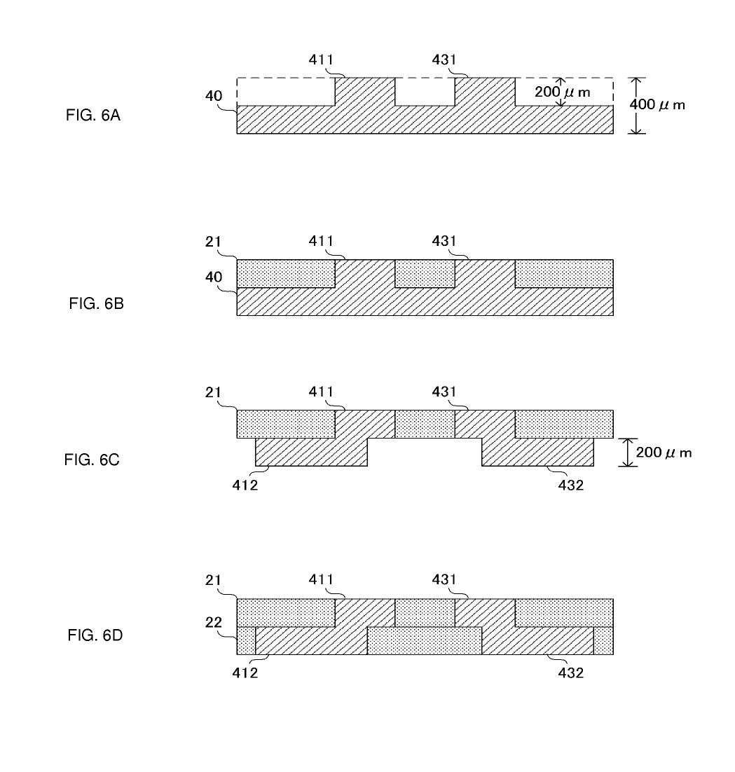

An example of a method of manufacturing the circuit board 1 according to the second preferred embodiment will now be described. FIGS. 6A-6D are schematic diagrams sequentially illustrating a process of manufacturing the circuit board 1 according to the second preferred embodiment. FIGS. 6A-6D illustrate a cross-sectional view taken along line V-V of FIG. 5A in the manufacturing process.

In a first step (FIG. 6A), a photosensitive resist film is deposited on the top and bottom surfaces of a copper sheet 40 having a thickness of 400 μm, and exposure, development, and etching are performed by a subtractive method in such a manner that a rectangular pattern having a thickness of 200 μm is left behind. The pattern that is left behind by etching is the upper wiring portions 411, 421, and 431.

In a second step (FIG. 6B), a portion in the top surface of the copper sheet 40 formed by removing the copper sheet 30 by etching is filled with an insulating resin 21. In this case, the portion is filled with the insulating resin 21 in such a manner that at least the top surface of the pattern that is left behind by etching (the upper wiring portion 411 and the like) is exposed. The insulating resin 21 is, for example, a polyimide resin, and after the portion is filled with the insulating resin 21, the insulating resin 21 is pressed and cured.

In a third step (FIG. 6C), exposure, development, and etching are performed in such a manner that a rectangular or substantially rectangular pattern having a thickness of 200 μm that is partially superposed with the bottom surface of the pattern, which has been formed by etching in the first step (the upper wiring portion 411 and the like), is left behind on the bottom surface of the copper sheet 40. The pattern that is left behind by etching is the lower wiring portions 412, 422, and 432.

In a fourth step (FIG. 6D), a portion in the bottom surface of the copper sheet 40 formed by removing the copper sheet 30 by etching is filled with the insulating resin 22. In this case, the portion is filled with the insulating resin 22 in such a manner that at least the bottom surface of the pattern that is left behind by etching (the lower wiring portion 412 and the like) is exposed. The insulating resin 22 is, for example, a polyimide resin, and after the portion is filled with the insulating resin 22, the insulating resin 22 is pressed and cured. The insulating resins 21 and 22 are the insulating layer 2 illustrated in FIGS. 5A and 5D.

Through the first to fourth steps, the circuit board 1 that includes the wiring portions 41, 42, and 43, which are integrally formed of a single copper sheet, can be manufactured.

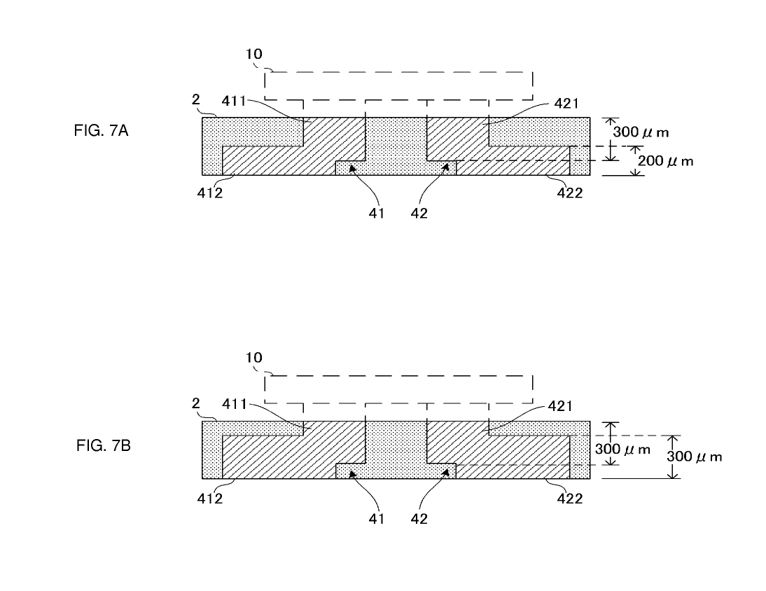

Note that, although the thicknesses of the upper wiring portion 411, the lower wiring portion 412, and the like preferably are 200 μm and are the same as one another in the present preferred embodiment, the thicknesses or the like of the upper wiring portion 411, the lower wiring portion 412, and the like may be suitably changed. FIGS. 7A and 7B are diagrams illustrating another example of the circuit board 1 according to the second preferred embodiment. For example, as illustrated in FIG. 7A, the upper wiring portion 411 (or 421 or 431) having a thickness of 300 μm and the lower wiring portion 412 (or 422 or 432) having a thickness of 200 μm may be partially superposed with each other in a planar direction of the insulating layer 2.

Alternatively, as illustrated in FIG. 7B, the upper wiring portion 411 (or 421 or 431) and the lower wiring portion 412 (or 422 or 432) each of which has a thickness of 300 μm may be partially superposed with each other in the planar direction of the insulating layer 2.

In both of FIG. 7A and FIG. 7B, the thicknesses of the wiring portions 41, 42, and 43 can be increased, and thus, it is possible to make the circuit board 1 further capable of withstanding a large current.

### Third Preferred Embodiment

In a third preferred embodiment, a wiring portion includes a column along a thickness direction of an insulating layer 2. A difference between the third preferred embodiment and the first and the second preferred embodiments will be described below.

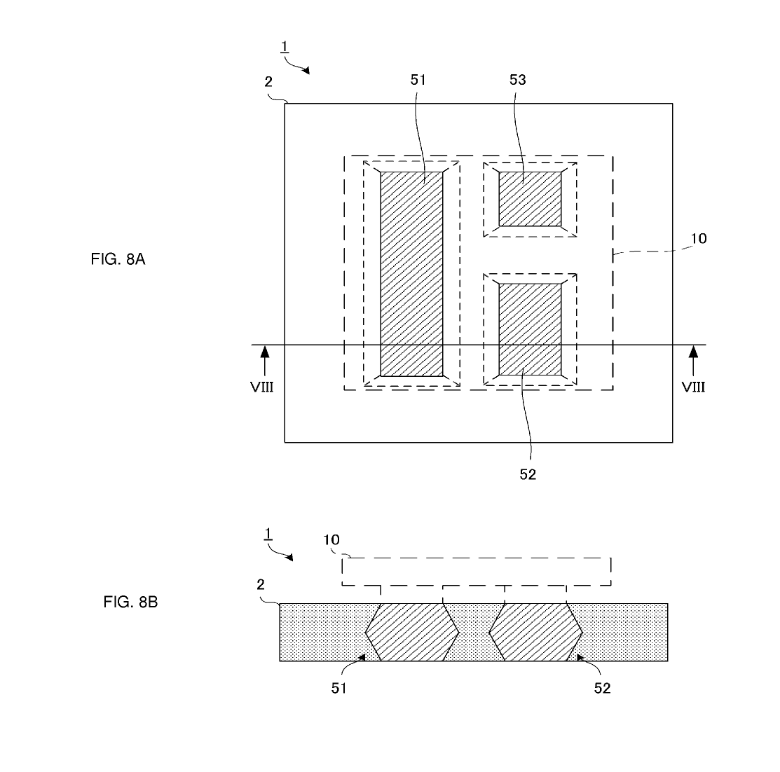

FIGS. 8A and 8B are schematic diagrams of a circuit board according to the third preferred embodiment. FIG. 8A is a top view of the circuit board. FIG. 8B is a cross-sectional view taken along line VIII-VIII of FIG. 8A.

A circuit board 1 according to the third preferred embodiment includes an insulating layer 2 and wiring portions 51, 52, and 53. The insulating layer 2 preferably is the same as that of the first preferred embodiment. In a manner similar to the first and second preferred embodiments, each of the wiring portions 51, 52, and 53 is preferably defined by a single copper sheet.

Each of the wiring portions 51, 52, and 53 includes top and bottom surfaces the sizes and shapes of which are the same as each other and has the column in which a center portion expands outward in an axial direction perpendicular or substantially perpendicular to the top and bottom surfaces. The axial direction of each of the wiring portions 51, 52, and 53 extends along a thickness direction of the insulating layer 2, and each of the wiring portions 51, 52, and 53 is provided on the insulating layer 2 such that the top and bottom surfaces thereof are exposed at the top and bottom surfaces of the insulating layer 2.

Since each of the wiring portions 51, 52, and 53 has a shape in which the center portion expands, each of the wiring portions 51, 52, and 53 does not easily come off from the insulating layer 2. In addition, in the present preferred embodiment, the thicknesses of the wiring portions 51, 52, and 53 in a planar direction of the insulating layer 2 can be increased, and thus, it is possible to make the circuit board 1 further capable of withstanding a large current.

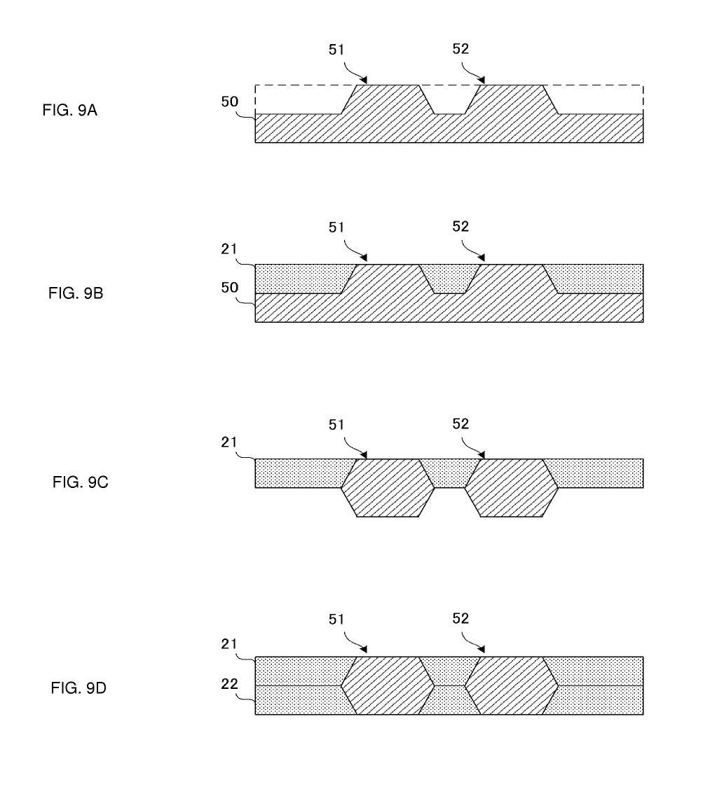

An example of a method of manufacturing the circuit board 1 according to the third preferred embodiment will now be described. FIGS. 9A-9D are schematic diagrams sequentially illustrating a process of manufacturing the circuit board 1 according to the third preferred embodiment. FIGS. 9A-9D are cross-sectional views taken along line VIII-VIII of FIG. 8A in the manufacturing process.

In a first step (FIG. 9A), a photosensitive resist film is deposited on the top and bottom surfaces of a copper sheet 50 having a thickness of 400 μm, and exposure, development, and etching are performed by a subtractive method in such a manner that patterns 511 and 512 each of which has a thickness of 200 μm and has a trapezoidal or substantially trapezoidal cross section are left behind. The patterns that are left behind by etching are upper portions of the wiring portions 51, 52, and 53.

In a second step (FIG. 9B), a portion in the top surface of the copper sheet 50 formed by removing the copper sheet 50 by etching is filled with an insulating resin 21. In this case, the portion is filled with the insulating resin 21 in such a manner that at least the top surface of the pattern that is left behind by etching is exposed. The insulating resin 21 is, for example, a polyimide resin, and after the portion is filled with the insulating resin 21, the insulating resin 21 is pressed and cured.

In a third step (FIG. 9C), exposure, development, and etching are performed in such a manner that patterns, each of which has a shape the same as that of a corresponding one of the patterns formed in the first step and each of which has a thickness of 200 μm, are left behind on the bottom surface of the copper sheet 50. The patterns that are left behind by etching are lower portions of the wiring portions 51, 52, and 53.

In a fourth step (FIG. 9D), a portion in the bottom surface of the copper sheet 50 formed by removing the copper sheet 50 by etching is filled with the insulating resin 22. In this case, the portion is filled with the insulating resin 22 in such a manner that at least the bottom surface of each of the patterns that are left behind by etching is exposed. The insulating resin 22 is, for example, a polyimide resin, and after the portion is filled with the insulating resin 22, the insulating resin 22 is pressed and cured. The insulating resins 21 and 22 are the insulating layer 2 illustrated in FIG. 8.

Through the first to fourth steps, the circuit board 1 that includes the wiring portions 51, 52, and 53, which are integrally defined by a single copper sheet, can be manufactured.

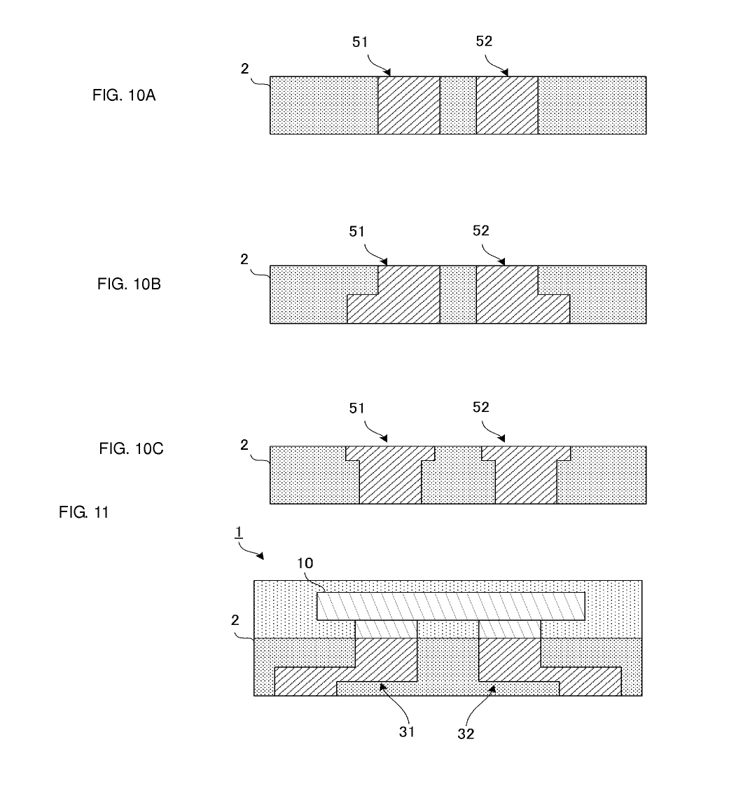

Note that, although each of the wiring portions 51, 52, and 53 includes the column in which a center portion in an axial direction perpendicular or substantially perpendicular to the top and bottom surfaces expands outward in the present preferred embodiment, the shape of the column may be suitably changed. FIGS. 10A-10C are diagrams illustrating another example of the circuit board 1 according to the third preferred embodiment. For example, as illustrated in FIG. 10A, each of the wiring portions 51, 52, and 53 may have a rectangular or substantially rectangular parallelepiped shape. Alternatively, as illustrated in FIG. 10B, each of the wiring portions 51, 52, and 53 may have a cross-sectioned shape which is L-shaped or substantially L-shaped, as illustrated in FIG. 10C, may have a cross-sectioned shape which is T-shaped or substantially T-shaped, for example.

Note that, design changes may be suitably made in the specific configuration or the like of the circuit board 1. The functions and effects described in the above-described preferred embodiments are merely the most preferred functions and effects obtained from the present invention, and the functions and effects of the present invention are not limited to those described in the above-described preferred embodiments.

For example, the semiconductor element 10 that is mounted on the circuit board 1 may be sealed with a thermosetting epoxy resin or the like. FIG. 11 is a schematic diagram illustrating a cross-sectional view of the circuit board 1 in which the semiconductor element 10 is sealed with a resin. As illustrated in FIG. 11, the semiconductor element 10 can be protected against a hot or humid environment by sealing the semiconductor element 10 with a resin.

Note that, although the circuit board 1 according to the first preferred embodiment is illustrated in FIG. 11, the circuit board may be any one of the circuit boards according to the first, second, and third preferred embodiments or may be the circuit board 1 of any one of the modifications illustrated in FIG. 4, FIG. 7, FIG. 10, and the like.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. A circuit board comprising:
an insulating layer; and
a wiring portion defined by a single electrically conductive metal member, the wiring portion being arranged on the insulating layer such that a portion of the wiring portion is exposed at each of top and bottom surfaces of the insulating layer.

3. The circuit board according to claim 2, wherein positions on the top and bottom surfaces of the insulating layer where portions of the wiring portion are exposed are not superposed with each other in a top-bottom direction of the insulating layer.

4. The circuit board according to claim 2, wherein the wiring portion includes a column extending along a top-bottom direction of the insulating layer and the column expands gradually from the top and bottom surfaces of the insulating layer to a center portion of the wiring portion in the top-bottom direction.

5. The circuit board according to claim 2, wherein a nickel plating film is located on portions of the wiring portion exposed at the top and bottom surfaces of the insulating layer.

6. The circuit board according to claim 2, wherein an electronic component is directly mounted on the portion of the wiring portion exposed at the top surface of the insulating layer.

7. The circuit board according to claim 6, wherein the electronic component is a power semiconductor element.

8. The circuit board according to claim 6, wherein the electronic component is sealed with a resin.

9. The circuit board according to claim 6, wherein the electronic component is one of a silicon semiconductor element, a gallium arsenide semiconductor element, a passive element, a capacitor, an inductor, and a power metal-oxide-semiconductor field-effect transistor.

10. The circuit board according to claim 2, wherein the insulating layer has a rectangular or substantially rectangular parallelepiped shape.

11. The circuit board according to claim 2, wherein the wiring portion includes a first wiring for a gate terminal of a semiconductor element, a second wiring for a source terminal of the semiconductor element, and a third wiring for a drain terminal of the semiconductor element.

12. The circuit board according to claim 2, wherein the wiring portion includes a plurality of different wirings defined by a single copper sheet.

13. The circuit board according to claim 12, wherein each of the plurality of different wirings has a rectangular or substantially rectangular column shape.

14. The circuit board according to claim 12, wherein each of the plurality of different wirings includes at least three wiring portions.

15. The circuit board according to claim 2, wherein positions on the top and bottom surfaces of the insulating layer where portions of the wiring portion are exposed are partially superposed with each other in a top-bottom direction of the insulating layer.

16. The circuit board according to claim 12, wherein each of the plurality of wirings includes top and bottom surfaces and a column in which a center portion expands outward in an axial direction perpendicular or substantially perpendicular to the top and bottom surfaces.

17. The circuit board according to claim 16, wherein the axial direction of each of the plurality of wirings extends along a thickness direction of the insulating layer, and each of the plurality of wirings is arranged on the insulating layer such that the top and bottom surfaces thereof are exposed at the top and bottom surfaces of the insulating layer.

18. The circuit board according to claim 16, wherein each of the plurality of wirings has a rectangular or substantially rectangular parallelepiped shape.

19. The circuit board according to claim 16, wherein each of the plurality of wirings is L-shaped or substantially L-shaped.

20. The circuit board according to claim 16, wherein each of the plurality of wirings is T-shaped or substantially T-shaped.

21. A method of manufacturing a circuit board comprising:
forming a wiring pattern by etching a first surface of a single electrically conductive metal member;
filling a portion in the first surface from which the metal member has been removed by etching with a dielectric material;
forming a wiring pattern by etching a second surface of the metal member; and
filling a portion in the second surface from which the metal member has been removed by etching with a dielectric material.
